(19) United States
(12) Patent Application Publication
(10) Pub. No.: US 2005/0128705 A1
(43) Pub. Date: Jun. 16, 2005

(54) Composite cold plate assembly

(75) Inventors: Richard C. Chu, Hopewell Junction, NY (US); Michael J. Ellsworth JR., Lagrangeville, NY (US); Roger R. Schmidt, Poughkeepsie, NY (US); Robert E. Simons, Poughkeepsie, NY (US)

Correspondence Address: Andrew J. Wojnicki, Jr.;IBM Corporation - MS P386, 2455 South Road, Poughkeepsie, NY, 12601, US

(73) Assignee: International Business Machines Corporation, Armonk, NY (US)

(21) Appl. No.: 10/736,949

(22) Filed: Dec. 16, 2003

(51) Int. Cl. H05K 7/20

(52) U.S. Cl. 361/699; 361/689

(57) ABSTRACT

A cooling fluid distribution assembly for a plurality of electronic modules, using a composite cold plate structure. One cold plate is associated with each electronic module requiring liquid cooling. Each cold plate includes a high thermal conductivity base sealably fastened to a cover, the cover having at least one fluid inlet and at least one fluid outlet. Cover fluid inlets and outlets are connected via a plurality of flexible, nonmetallic conduits, the conduits being bonded to the cover inlets and outlets. Each cold plate cover is formed of a material that is capable of being bonded to the flexible, nonmetallic conduits, covers are therefore formed of a different material than the material comprising the cold plate base. Cold plate structures preferably include internal fluid distribution structures. The resulting cooling fluid distribution assembly provides reliable fluid connections and is sufficiently flexible to adjust for variances in module height etc.

### FIELD OF THE INVENTION

The present invention relates in general to cooling of electronic systems. In particular, the present invention relates to a cooling fluid distribution apparatus for an electronic system having two or more fluid cooled electronic modules.

### BACKGROUND OF THE INVENTION

As is known, operating electronic devices produce heat. This heat should be removed from the devices in order to maintain device junction temperatures within desirable limits: failure to remove the heat thus produced results in increased device temperatures, potentially leading to thermal runaway conditions. Several trends in the electronics industry have combined to increase the importance of thermal management, including heat removal for electronic devices, including technologies where thermal management has traditionally been less of a concern, such as CMOS. In particular, the need for faster and more densely packed circuits has had a direct impact on the importance of thermal management. First, power dissipation, and therefore heat production, increases as the device operating frequencies increase. Second, increased operating frequencies may be possible at lower device junction temperatures. Finally, as more and more devices are packed onto a single chip, power density (Watts/cm²) increases, resulting in the need to remove more power from a given size chip or module. These trends have combined to create applications where it is no longer desirable to remove the heat from modern devices solely by traditional air cooling methods, such as by using traditional air cooled heat sinks.

As is also known, electronic devices are more effectively cooled through the use of a cooling fluid, such as chilled water or a refrigerant. For example, electronic devices may be cooled through the use of a cold plate in thermal contact with the electronic devices. Chilled water (or other cooling fluid) is circulated through the cold plate, where heat is transferred from the electronic devices to the cooling fluid. The cooling fluid then circulates through an external heat exchanger or chiller, where the accumulated heat is transferred from the cooling fluid. Fluid flow paths are provided connecting the cold plates to each other and to the external heat exchanger or chiller. These fluid flow paths are constructed of conduits such as, for example, copper tubing, which are typically joined to cold plates by one or more mechanical connections.

Modern electronic systems often include many electronic devices in need of the enhanced cooling provided by such a fluid based cooling system. In such systems, where two or more electronic devices are located in close physical proximity, it is frequently desirable to manifold or plumb together the cold plates associated with the electronic devices into a multi-cold plate fluid distribution assembly. Such an assembly may be constructed in a way that reduces or minimizes the number of cooling fluid inlets to the assembly, and the number of cooling fluid outlets from the assembly. Reducing or minimizing the number of cooling fluid inlets and outlets also minimizes the number of mechanical conduit connections required to provide cooling fluid to all cold plates within the assembly. For example, a group of four cold plates, plumbed individually, requires eight connections: one inlet and one outlet per cold plate. By plumbing the four cold plates into a single assembly, the eight connections may be reduced, or minimized to two connections (one assembly inlet, one assembly outlet). Since mechanical conduit connections are often a point of cooling system failure, it is desirable to reduce or minimize the number of mechanical conduit connections by manifolding multiple cold plates into a multi-cold plate fluid distribution assembly, thereby improving system reliability by reducing the number of system points of failure.

A multi-cold plate fluid distribution assembly constructed using known methods and materials, however, may not provide sufficient flexibility to maintain adequate thermal contact with all associated electronic devices. Manufacturing and assembly tolerances in electronic devices, boards, cold plates, etc., may result in variations in component dimensions and alignment, requiring some degree of flexibility in the multi-cold plate fluid distribution assembly in order to simultaneously maintain good thermal contact with all associated electronic devices. For example, manufacturing and process tolerances may cause similar types of modules, such as processor modules, to vary in height by several millimeters. Furthermore, it may be desirable to manifold cold plates associated with different types of electronic devices, where relative tolerances may result in greater height differences, alignment differences, etc. Constructing a multi-cold plate fluid distribution assembly using known materials and methods, such as using copper or other metal tubing soldered or brazed to several metal cold plates, results in an assembly that may lack sufficient flexibility to maintain good thermal contact in the presence of normal manufacturing and assembly process variations.

Alternatively, known materials and methods may be used to create a multi-cold plate fluid distribution assembly having sufficient flexibility but which lacks the reliability improvements associated with a reduced number of mechanical conduit connections. For example, a number of metal cold plates may be plumbed together using flexible tubing, such as plastic tubing. Since plastic tubing cannot be soldered, brazed, or otherwise reliably and permanently joined to a metal cold plate, a mechanical connection is required between the plastic tubing and each inlet and outlet of each cold plate. As previously noted, increasing the number of mechanical conduit connections increases the potential points of failure in the cooling distribution assembly. Thus, known materials and methods may provide a multi-cold plate fluid distribution assembly that is sufficiently flexible to maintain good thermal contact with associated electronic devices in the presence of normal manufacturing and assembly process variations, however such flexibility is obtained at the expense of the reliability improvement that served as motivation for creating the multi-cold plate fluid distribution assembly.

For the foregoing reasons, therefore, there is a need in the art for a multi-cold plate fluid distribution assembly that is simultaneously capable of providing a reliability benefit by reducing mechanical conduit connections, while also providing sufficient assembly flexibility to maintain good thermal contact between assembly cold plates and their associated electronic devices in the presence of normal manufacturing and assembly process tolerances.

### SUMMARY

The shortcomings of the prior art are overcome, and additional advantages realized, through the provision of a multi-cold plate fluid distribution assembly utilizing a composite cold plate structure.

In one aspect, the present invention involves a cooling fluid distribution assembly for a plurality (i.e., two or more) of electronic modules, the assembly including a plurality of cold plates and a plurality of flexible, nonmetallic fluid distribution conduits. Each of the plurality of cold plates is associated with one of the plurality of electronic modules, and each cold plate includes: a high thermal conductivity cold plate base; a nonmetallic cold plate cover having at least one cover fluid inlet and at least one cover fluid outlet, the cold plate cover being sealably affixed to the cold plate base; and a fluid circulation structure for directing fluid flow from the at least one cover fluid inlet to the at least one cover fluid outlet. The plurality of flexible, nonmetallic fluid distribution conduits are bonded to, and in fluid communication with, the cover fluid inlets and cover fluid outlets. The cold plates and conduits thus form an assembly for distributing a cooling fluid to the plurality of electronic modules, the assembly having at least one assembly fluid inlet and at least one assembly fluid outlet, the assembly further having connectors only at the assembly fluid inlet(s) and assembly fluid outlet(s).

In a further aspect, the present invention involves an electronic module assembly capable of being cooled by a fluid, the assembly including a plurality of electronic module substrate assemblies, a plurality of cold plates, and a plurality of flexible, nonmetallic fluid distribution conduits. Each of the plurality of electronic module substrate assemblies includes a substrate and at least one electronic device electrically connected to the substrate. Each of the plurality of cold plates is associated with one of the plurality of electronic modules, and each cold plate includes: a high thermal conductivity cold plate base, the cold plate base also providing a high thermal conductivity module cap; a nonmetallic cold plate cover having at least one cover fluid inlet and at least one cover fluid outlet, the cold plate cover being sealably affixed to the cold plate base; and a fluid circulation structure for directing fluid flow from the at least one cover fluid inlet to the at least one cover fluid outlet. The plurality of flexible, nonmetallic fluid distribution conduits are bonded to, and in fluid communication with, the cover fluid inlets and cover fluid outlets. The cold plates and conduits thus form an assembly for distributing a cooling fluid to the plurality of electronic modules, the assembly having at least one assembly fluid inlet and at least one assembly fluid outlet, the assembly further having connectors only at the assembly fluid inlet(s) and assembly fluid outlet(s).

It is therefore an object of the present invention to provide a a multi-cold plate fluid distribution assembly utilizing a composite cold plate structure.

It is a further object of the present invention to provide a multi-cold plate fluid distribution assembly that is simultaneously capable of providing a reliability benefit by reducing mechanical conduit connections, while also providing sufficient assembly flexibility to maintain good thermal contact between assembly cold plates and their associated electronic devices in the presence of normal manufacturing and assembly process tolerances.

The recitation herein of a list of desirable objects which are met by various embodiments of the present invention is not meant to imply or suggest that any or all of these objects are present as essential features, either individually or collectively, in the most general embodiment of the present invention or in any of its more specific embodiments.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the concluding portion of the specification. The invention, however, both as to organization and method of practice, together with further objects and advantages thereof, may best be understood by reference to the following description taken in connection with the accompanying drawings in which:

FIG. 1 illustrates an isometric view of a cooling fluid distribution assembly per an embodiment of the present invention;

FIG. 2 illustrates an exploded view of a cold plate assembly per an embodiment of the present invention;

FIG. 3A illustrates a plan view of a cold plate cover and fluid circulation structure per an embodiment of the present invention;

FIG. 3B illustrates a plan view of a cold plate cover and fluid circulation structure per an embodiment of the present invention;

FIG. 4A illustrates a plan view of a series fluid distribution assembly per an embodiment of the present invention;

FIG. 4B illustrates a plan view of a parallel fluid distribution assembly per an embodiment of the present invention;

FIG. 5A illustrates a sectional view of a module assembly plus cold plate assembly per an embodiment of the present invention;

FIG. 5B illustrates a sectional view of a module assembly plus cold plate assembly per an embodiment of the present invention; and

FIG. 6 illustrates a sectional view of an integrated module and cold plate assembly per an embodiment of the present invention.

### DETAILED DESCRIPTION OF THE INVENTION

In accordance with preferred embodiments of the present invention, a multi-cold plate fluid distribution assembly utilizing a composite cold plate structure is disclosed herein.

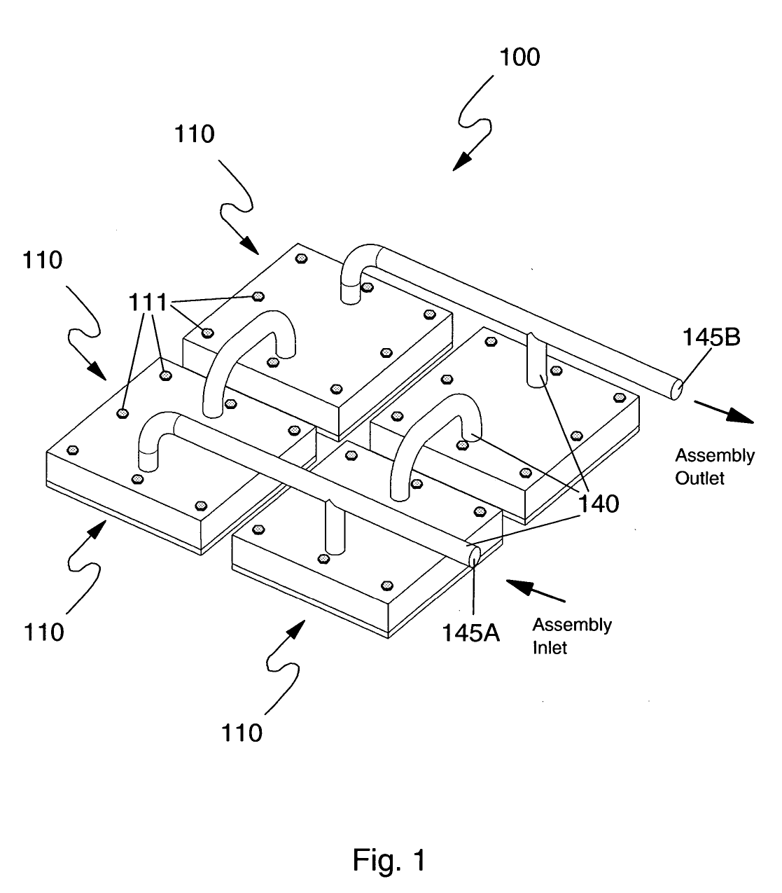

FIG. 1 illustrates a multi-cold plate fluid distribution assembly, per an embodiment of the present invention. The assembly of FIG. 1 is exemplary only; other assembly configurations are envisioned within the spirit and scope of the present invention. As illustrated in FIG. 1, a fluid distribution assembly of the present invention includes a plurality of cold plates 110: in the exemplary embodiment of FIG. 1, assembly 100 includes four cold plates 110. The teachings of the present invention are applicable to any system having two or more electronic modules: as used herein, therefore, the term plurality equates to a quantity of two or more. Assembly 100 also includes a plurality of flexible, nonmetallic conduits 140. Conduits 140 are sealably affixed to cold plates 110, thereby creating fluid distribution assembly 100. In the embodiment illustrated in FIG. 1, assembly 100 includes one assembly fluid inlet 145A, and one assembly fluid outlet 145B. Each cold plate 110 is assembled using a plurality of mechanical fasteners 111, such as threaded bolts, screws, or the like. At least four fasteners 111 are required, one per cold plate comer. Additional fasteners 111 may be used in larger cold plate designs, such as the 8 fasteners 111 per cold plate illustrated in FIG. 1.

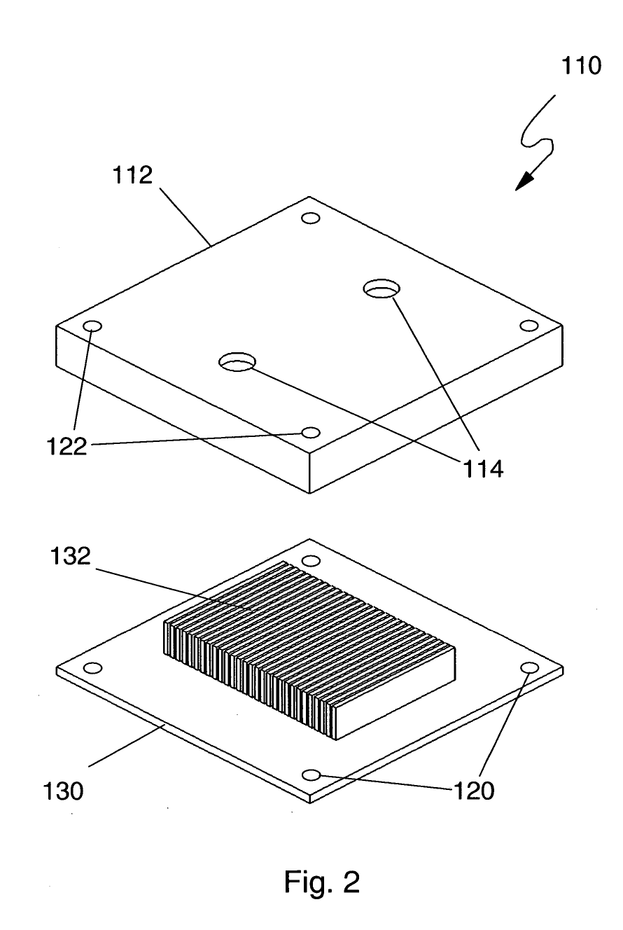

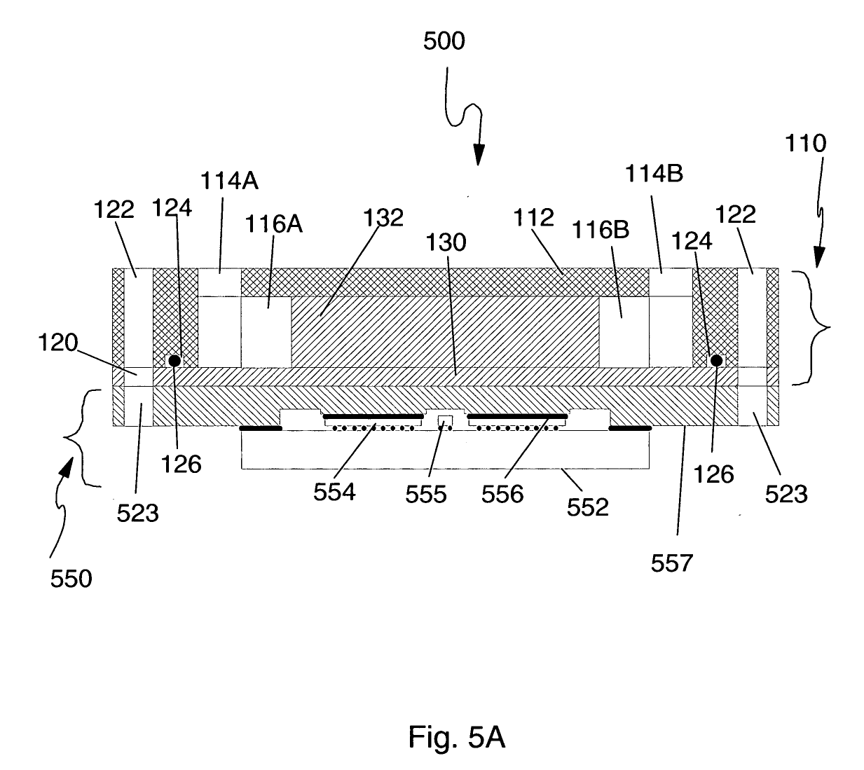

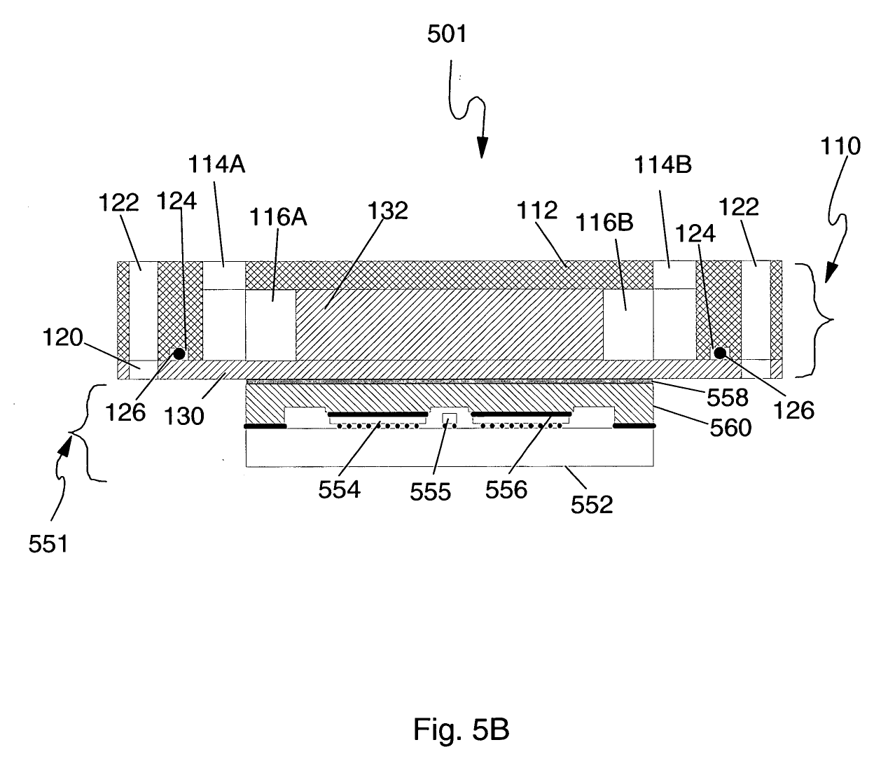

FIG. 2 illustrates further details of a cold plate 110, such as cold plates 110 illustrated in assembly 100 of FIG. 1. Cold plate 110 includes two primary components: base 130, and cover 112. Base 130 provides a high thermal conductivity connection to an electronic module. In preferred embodiments of the present invention, base 130 is composed of a high thermal conductivity metal, such as, for example, copper, aluminum, etc. Cover 112 includes two fluid connections 114; one connection 114 providing a fluid inlet, the other connection 114 providing a fluid outlet. In preferred embodiments of the present invention, cover 112 is composed of a material that is capable of being sealably and permanently bonded to flexible, nonmetallic conduits 140. In preferred embodiments of the present invention, conduits 140 and cover 112 are composed of plastic, and are bonded by any of several methods known in the art such as: chemical bonding, glue, epoxy, etc. Cover 112 is formed using processes known in the art, such as a molding process or the like. Unlike conduits 140, cover 112 is preferably rigid. Cover 112 includes a plurality of through holes 122: the embodiment illustrated in FIG. 2 depicts four holes 122, one per comer. Base 130 includes a plurality of holes 120, matching holes 122 in number and location. Holes 120 may be either through holes or threaded holes. In preferred embodiments of the present invention, cover 112 and base 130 are mechanically joined using connectors as known in the art, such as threaded bolts; a fluid tight seal is obtained using methods known in the art, such as a gasket, O-ring, or the like (see FIG. 5 and associated description).

Cold plate structures of the present invention further include an internal fluid circulation structure to direct the flow of cooling fluid from the cover inlet, over a region of base 130 nearest the electronic device or devices from which heat is to be removed, and finally to the cover outlet. The internal fluid circulation structure may be formed entirely within cover 112, or entirely within base 130, or partially within cover 112 and partially within base 130. In preferred embodiments of the present invention, an internal fluid circulation structure is formed partially within cover 112 and partially within base 130.

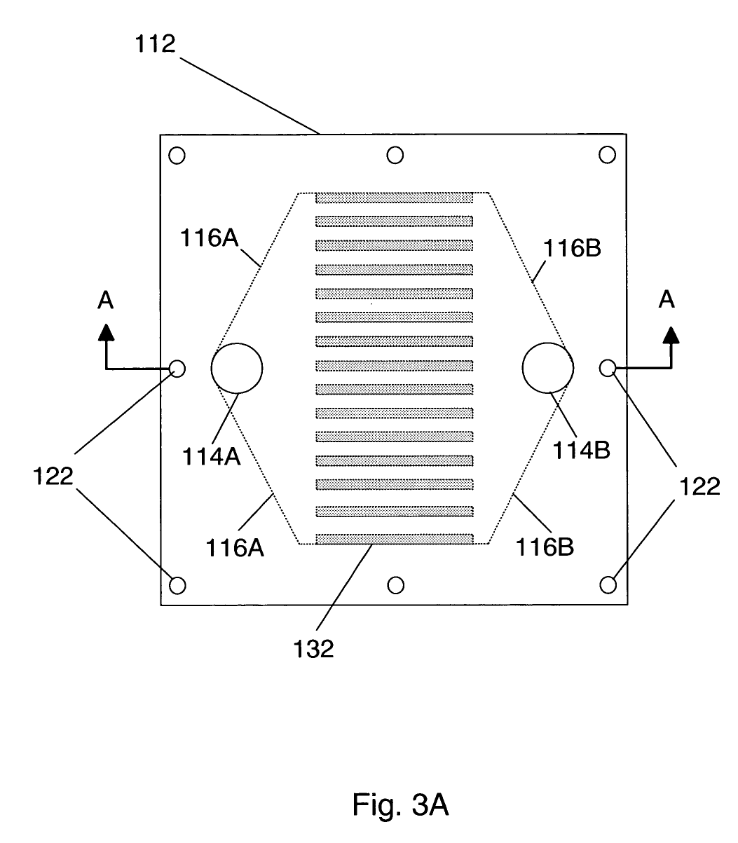

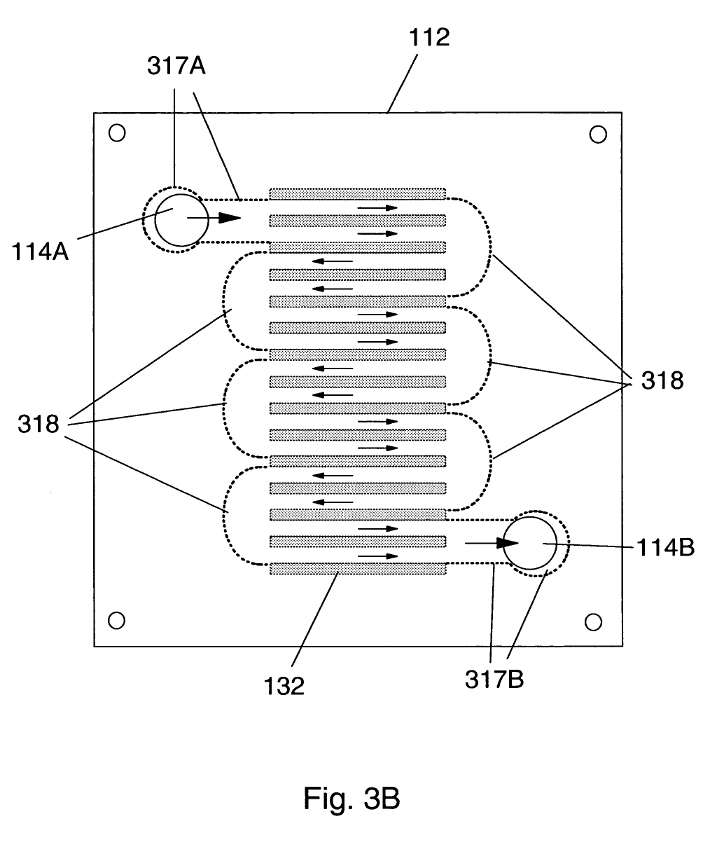

FIGS. 2 and 3 illustrate preferred embodiments of the base and cover circulation components, respectively. FIG. 2 illustrates a set of high thermal conductivity fins 132, which form a plurality of fluid channels disposed between fins 132. Fins 132 are mechanically and thermally connected to base 130, and are ideally formed of a high thermal conductivity metal such as, for example, copper or aluminum. A variety of methods may be used to form base 130 with fins 132. For example, a solid block of copper may be bonded to base 130, fins 132 may then be formed using an operation as known in the art, such as sawing or milling, for example.

FIGS. 3 illustrate two embodiments of cover circulation components in relation to fluid channels formed by fins 132. FIG. 3A illustrates a plenum arrangement creating parallel flow through channels formed by fins 132, and FIG. 3B illustrates an end manifold subsection arrangement creating serial, serpentine flow through channels formed by fins 132. Both FIGS. 3A and 3B depict a top view of a cold plate assembly such as assembly 110 of FIG. 1, without fasteners 111. Fluid circulation components are therefore illustrated as hidden features: cover fluid circulation components are located on the underside of cover 112, and base fluid circulation components (i.e., fins 132) are located on the upper portion of base 130.

Cover 112 of the embodiment illustrated in FIG. 3A includes a cover fluid inlet 114A, and a cover fluid outlet 114B. Cover 112 further includes an inlet plenum or manifold 116A and an outlet plenum or manifold 116B, both located on the underside of cover 112. Each plenum 116 consists of a vertical wall (when assembly 110 is viewed from the side), extending from cover 112 to the upper surface of base 130, preferably formed during the same molding process used to form cover 112. Inlet plenum 116A provides a fluid flow path from inlet 114A to channels formed by fins 132: fluid is directed in parallel to all channels formed by fins 132 from inlet 114A. In similar fashion, outlet plenum 116B provides a fluid flow path from channels formed by fins 132 to cover outlet 114B: fluid is collected in parallel from all channels formed by fins 132 and directed to outlet 114B. During assembly of cold plate 100, inlet plenum 116A and outlet plenum 116B sealably mate with fins 132 located on base 130, thereby forming a closed fluid path from inlet 114A to outlet 114B. In alternative embodiments of the present invention, cover 112 may further include gasket material in the region located directly above fins 132, and at the base of plenum walls 116 (not illustrated).

FIG. 3B illustrates fluid flow components of an assembly 110 per another embodiment of the present invention. Cover conduits 317 and manifold subsections 318 are located on the underside of cover 112. When cover 112 is assembled onto base 130, cover components 317 and 318 sealably mate with base fins 132 to form a closed fluid flow path from inlet 114A to outlet 114B. Each cover component 317 and 318 consists of a vertical wall (when assembly 110 is viewed from the side), extending from cover 112 to the upper surface of base 130, preferably formed during the same molding process used to form cover 112. Conduits 317 include two sections: a curved conduit section surrounding a portion of inlets/outlets 114, and a substantially straight conduit section connecting the curved conduit section and one of more channels formed by fins 132. In the embodiment illustrated in FIG. 3B, cover conduits 317 and manifold subsections 318 direct fluid flow from inlet 114A, through channels formed by fins 132, to outlet 114B. As illustrated in FIG. 3B, one end of inlet conduit 317A is in fluid flow communication with inlet 114A, and the opposing end of conduit 317A is in fluid flow communication with one or more of channels formed by fins 132. Conduit 317A thus directs fluid flow from inlet 114A to one or more (but not all) channels formed by fins 132. Manifold subsections 318 place one end of one or more channels formed by fins 132 in fluid communication with an adjacent end of an equal number of channels, thereby causing fluid flow in the second set of channels in a direction opposed to the flow of fluid through the first set of channels. Subsequent manifold subsections 318 provide a similar function, creating a serial serpentine flow through channels formed by fins 132. As illustrated in FIG. 3B, one end of outlet conduit 317B is in fluid flow communication with outlet 114B, and the opposing end of conduit 317B is in fluid flow communication with one or more of channels formed by fins 132. When the cooling fluid reaches the last set of channels formed by fins 132, the fluid flows into outlet conduit 317B, then to cover outlet 114B. In alternative embodiments of the present invention, cover 112 may further include gasket material in the region located directly above fins 132, and at the base of cover components 317 and 318 (not illustrated).

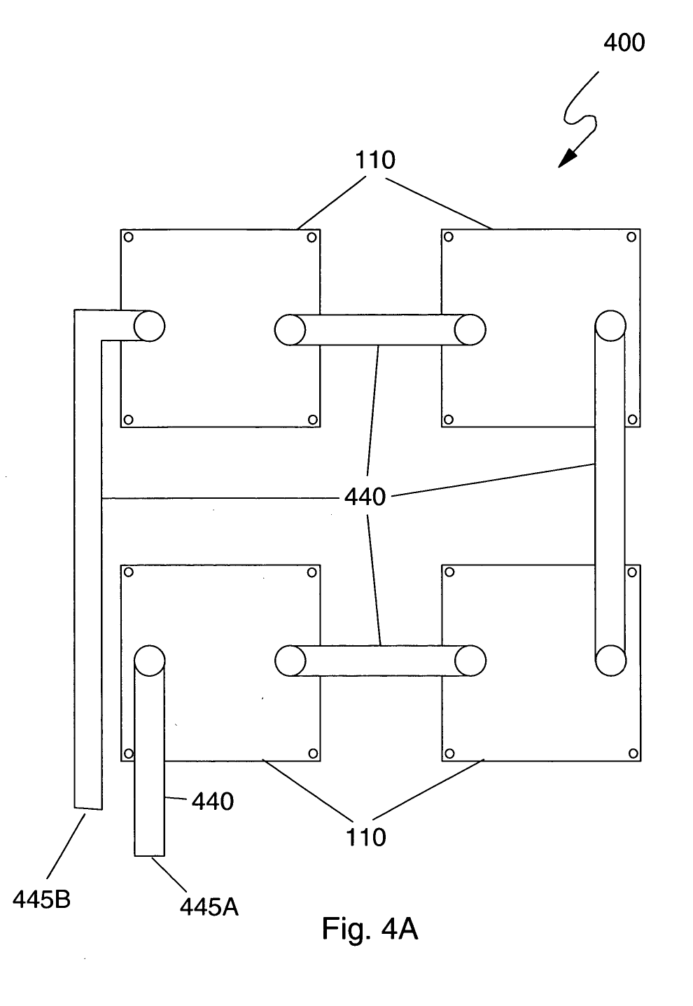

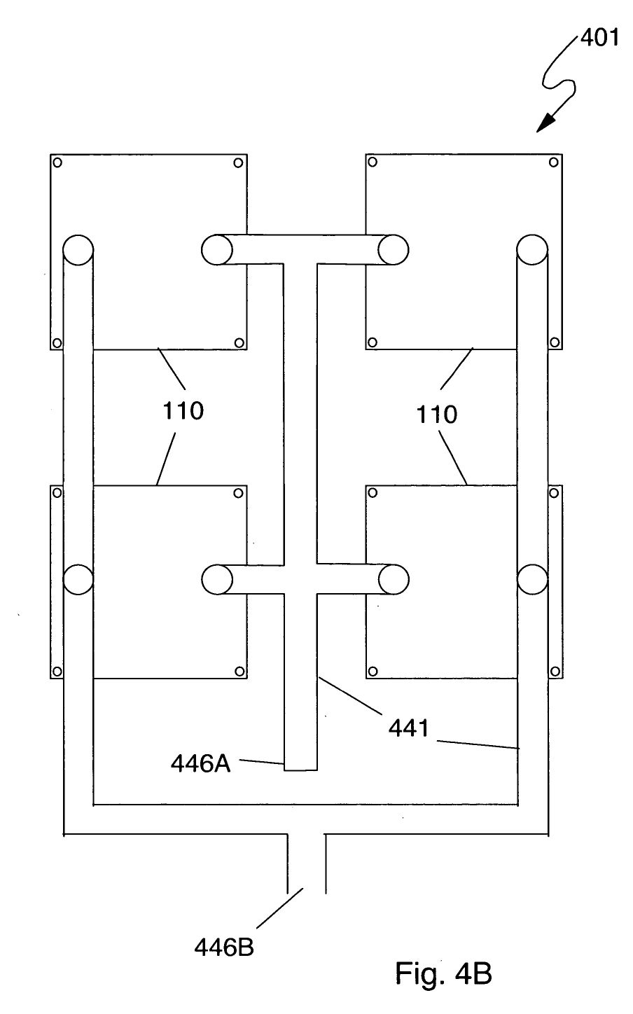

FIGS. 1 and 4 illustrate a variety of embodiments, each depicting an alternative structure for connecting the cold plates and flexible conduits. For example, FIG. 4A illustrates an embodiment of the present invention providing serial fluid flow among cold plates 110. In the embodiment of FIG. 4A, one cooling assembly inlet 445A is provided by one of a plurality of conduits 440: this conduit 440 is in fluid flow communication with a cover inlet of a first cold plate 110. Another conduit 440 provides a fluid flow connection from the outlet of the first cold plate 110 to the inlet of a second cold plate 110, etc. In this manner, fluid flows from assembly inlet 445A, serially from one cold plate to another, then to assembly fluid outlet 445B. Also for example, FIG. 4B illustrates an embodiment of the present invention providing parallel fluid flow among cold plates 110. In the embodiment of FIG. 4B, one cooling assembly inlet 446A is provided by one of two conduits 441: this inlet conduit is in fluid flow communication with a cover inlet of each cold plate 110 within assembly 401. FIG. 4B also illustrates a single assembly outlet 446B provided by the other conduit 441: this outlet conduit is in fluid flow communication with a cover outlet of each cold plate 110 within assembly 401. In assembly 401, therefore, fluid flows into the assembly through assembly inlet 446A, then in parallel to the cover inlet of all cold plates 110 within the assembly, through each cold plate 110 to its corresponding cover outlet, through outlet conduit 441 and finally to assembly outlet 446B.

A further alternative is illustrated in FIG. 1, where a combination series and parallel flow is achieved by connecting assembly inlet 145A to cover inlets of two cold plates 110. Flexible conduits 140 then connect the cover outlets of the first two cold plates with cover inlets of the remaining two cold plates. A final conduit 140 connects the cover outlets of the last two cold plates to assembly outlet 145B. In embodiments of the present invention having a different number of cold plates 110, a variety of configurations may be achievable in a combination series and parallel flow arrangement. In general, combination series and parallel flow is achieved by first dividing the cold plates into a plurality of groups, each group having a plurality of cold plates. Conduits are arranged to provide parallel fluid flow to and from all cold plates within a group, and serial flow between groups.

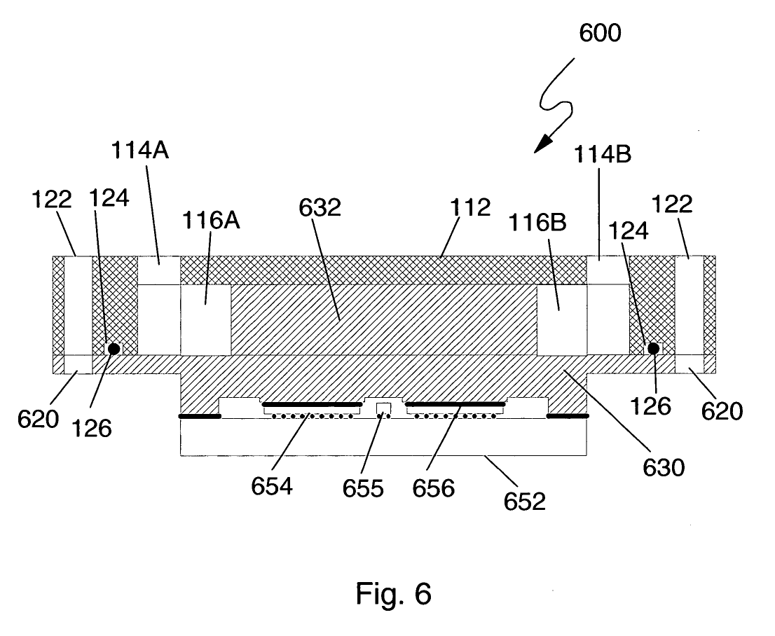

While the conduit embodiments of FIGS. 1 and 4 are illustrated in connection with the cold plate embodiments of FIGS. 1 through 3, each of the conduit embodiments are also combinable with alternative embodiments of cold plates and cold plate/module assemblies, such as the embodiments illustrated in FIGS. 5A, 5B, and 6.

FIGS. 5A, 5B, and 6 illustrate various embodiments of electronic module plus cold plate assemblies of the present invention. FIGS. 5A, 5B, and 6 each depict a sectional view of a module plus cold plate assembly, viewed along line A-A of the cold plate assembly depicted in FIG. 3A. These views are exemplary only: the assembly embodiments of FIGS. 5A, 5B, and 6 are also combinable with other cover embodiments, such as the serial flow embodiment depicted in FIG. 3B.

FIG. 5A illustrates further details of a cold plate assembly in relation to a module assembly, per an embodiment of the present invention. Assembly 500 includes cold plate assembly 110 and module assembly 550. Module assembly 550 includes substrate 552, to which electronic devices such as one or more semiconductor chips 554, and one or more passive devices such as capacitor 555 are electrically connected. In preferred embodiments of the present invention, semiconductor chips 554 are connected using controlled collapse chip connections (C4s) or similar flip-chip mounting technology, thereby enabling module cap 557 to be in thermal contact with most of the chip backside area via thermal material 556. A thermal path between chips 554 and cold plate 110 is thus provided by thermal material 556 and module cap 557: cap 557 is therefore formed of a material having high thermal conductivity. Thermal material 556 is a thermal grease, paste, or oil, as known in the art. In preferred embodiments of the present invention, cap 557 is formed of copper, however other materials as known in the art may be used, such as aluminum, alumina, aluminum nitride, ceramic, etc. Cap 557 is connected to substrate 552 by any of a variety of methods as known in the art, such as epoxy, mechanical fasteners (not shown), etc.

As previously discussed, cold plate 110 is comprised of a high thermal conductivity base 130 and a cover 112. In the embodiment of FIG. 5A, module cap 557 is substantially the same size and shape as base 130 and cover 112 (when viewed from the top, as in FIG. 3A). In this embodiment, fasteners 111 (not shown in FIG. 5A) are used to fasten cover 112, base 130, and cap 557 together. As illustrated in FIG. 5A, base 130 and cover 112 include a plurality of holes 120 and 122, respectively, through which a threaded bolt or other fastening device is used to mechanically fasten cover 112 and base 130 to module cap 557. In the embodiment of FIG. 5A, cap 557 includes a plurality of holes 523, one hole 523 associated with and located below each hole 120. In preferred embodiments, hole 523 is threaded. A gasket or O-ring 126 is provided to prevent cooling fluid leakage. In the embodiment illustrated in FIG. 5A, O-ring 126 is seated in a recessed area such as groove 124 of cover 112. An internal fluid circulation structure is provided by inlet 114A, inlet plenum 116A, channels formed by high thermal conductivity fins 132, outlet plenum 116B, and outlet 114B.

FIG. 5B depicts an alternative embodiment of the present invention, in which a cold plate is attached to a module having a module cap that does not extend to the edges of the cold plate. Assembly 501 includes cold plate 110 and module 551. Cold plate 110 is similar to cold plate 110 illustrated in FIG. 5A, except with respect to holes 120. As in the embodiment of FIG. 5A, module 551 includes substrate 552, one or more semiconductor chips 554, one or more passive devices such as capacitor 555, and thermal material 556 between chips 554 and a module cap. Materials and assembly methods are also as described with respect to the embodiment of FIG. 5A. Unlike the embodiment of FIG. 5A, however, module 551 includes a module cap 560 that does not extend to the edges of cold plate 110. In the embodiment of FIG. 5B, therefore, holes 120 in base 130 are preferably threaded, and are used in conjunction with fasteners 111 (not shown) to mechanically fasten cover 112 to base 130. In the embodiment depicted in FIG. 5B, base 130 is substantially the same thickness throughout. In alternative embodiments, base 130 is thicker in the edge regions around holes 120, thereby increasing the thread count within holes 120. The thickness of base 130 is increased in the edge regions either by maintaining a flat upper surface of base 130 and extending a lower surface of base 130 in the edge regions, by maintaining a flat lower surface of base 130 and extending an upper surface of base 130 in the edge regions, or by extending both upper and lower surfaces of base 130 in the edge regions. In embodiments where an upper surface of base 130 is extended in the edge regions, cover 112 is reduced in thickness by a corresponding amount in the edge region above the extended upper surface of base 130. As in the embodiment of FIG. 5A, a gasket or O-ring 126 is provided to prevent cooling fluid leakage. In the embodiment illustrated in FIG. 5B, O-ring 126 is seated in a recessed area such as groove 124 of cover 112. An internal fluid circulation structure is provided by inlet 114A, inlet plenum 116A, channels formed by high thermal conductivity fins 132, outlet plenum 116B, and outlet 114B.

As illustrated in FIG. 5B, assembly 501 includes cold plate assembly 110 in thermal contact with module assembly 551, using bonding material 558. In particular, a lower surface of cold plate base 130 is bonded to an upper surface of cap 560. In preferred embodiments of the present invention, bonding material 558 provides a mechanical bond and introduces minimal thermal resistance into the thermal path from chips 554 to a cooling fluid within cold plate 110. In preferred embodiments of the present invention, bonding material 558 is a thermally enhanced epoxy as known in the art.

The embodiments depicted in FIGS. 5A and 5B are advantageous in circumstances where cold plates 110 are used in connection with existing modules, such as modules 550 or 551. In particular, the embodiment of FIG. 5B provides the ability to attach cold plate assembly 110 to an upper surface of any module having an area that is smaller than the area of cold plate 110, without requiring a matching module cap such as cap 557 of FIG. 5A. In some circumstances, however, it may be desirable to reduce the thermal path between semiconductor chips, such as chips 554, and a cooling fluid. In applications where a lower resistance thermal path is desirable, and where sufficient design flexibility exists to accommodate alternative module designs, a lower resistance thermal path is achievable by integrating cold plate 110 and module 550. One example of a lower resistance thermal path embodiment is illustrated in FIG. 6.

FIG. 6 illustrates an exemplary embodiment of an assembly 600 having a lower resistance thermal path from chips 654 to a cooling fluid, per one or more embodiments of the present invention. Assembly 600 includes cold plate cover 112, as previously discussed. Cold plate cover 112 includes inlet 114A, inlet plenum 116A, outlet plenum 116B, outlet 114B, O-ring 126 seated in recess 124, and mounting holes 122. Two components of assembly 500 are integrated into a single component in assembly 600: module cap 557 and cold plate base 130 are replaced in assembly 600 by integrated cold plate base and module cap 630 (hereinafter, integrated base-cap). Integrated base-cap 630 is constructed of a high thermal conductivity material, such as, for example, copper or aluminum. Integrating cap 557 and base 130 eliminates bonding material 558 of FIG. 5B and its associated thermal resistance, as well as the thermal resistance associated with the thermal interfaces between base 130 and module cap 557 or cap 560. Thus, the embodiment of FIG. 6 provides a thermal path from chip to cooling fluid having lower thermal resistance than the embodiments of FIG. 5, assuming that integrated base-cap 630 is constructed of a material having similar thermal properties to those of caps 557 or 560, and base 130 used in the embodiments of FIG. 5. As illustrated in FIG. 6, integrated base-cap includes holes 620 aligned with cover holes 122: in preferred embodiments of the present invention, cover 112 is mechanically fastened to integrated base-cap 630 using threaded bolts or other fasteners as known in the art, through aligned holes 122 and 620. In preferred embodiments of the present invention, base holes 620 are threaded. As discussed with respect to the embodiment of FIG. 5B, base 630 may be increased in thickness in the edge regions around holes 620, increasing the thread count within holes 620. Integrated base-cap also provides channels formed by high conductivity fins 632, similar in function, materials, and construction techniques to channels formed by fins 132 of the embodiments illustrated in FIGS. 1 through 5.

While the invention has been described in detail herein in accord with certain preferred embodiments thereof, many modifications and changes therein may be effected by those skilled in the art. Accordingly, it is intended by the appended claims to cover all such modifications and changes as fall within the true spirit and scope of the invention.

1. A cooling fluid distribution assembly for a plurality of electronic modules, said assembly comprising:
a plurality of cold plates, each of said cold plates associated with one of said plurality of electronic modules, each of said cold plates having:
a high thermal conductivity cold plate base;
a nonmetallic cold plate cover having at least one cover fluid inlet and at least one cover fluid outlet, said cover being sealably affixed to said base; and
a fluid circulation structure for directing fluid flow from said at least one cover fluid inlet to said at least one cover fluid outlet;
a plurality of flexible, nonmetallic fluid distribution conduits in fluid flow communication with said cover fluid inlets and cover fluid outlets, said conduits being bonded to said cover fluid inlets and cover fluid outlets; and
wherein said cold plates and conduits form an assembly for distributing a cooling fluid to said plurality of electronic modules, said assembly having at least one assembly fluid inlet and at least one assembly fluid outlet, said assembly having connectors only at said at least one assembly fluid inlet and said at least one assembly fluid outlet.

2. The assembly of claim 1, said assembly having one assembly fluid inlet and one assembly fluid outlet.

3. The assembly of claim 1, wherein said fluid circulation structure comprises:
a plurality of high thermal conductivity fins in thermal and mechanical contact with said base, said fins forming a plurality of fluid flow channels;
an input plenum in said cover, said input plenum in fluid flow communication with said cover inlet, said input plenum in fluid flow communication with one opening of each of said plurality of channels;
an outlet plenum in said cover, said output plenum in fluid flow communication with an opposing opening of each of said plurality of channels, said output plenum in fluid flow communication with said cover outlet; and
wherein said input plenum, said channels, and said output plenum direct fluid flow from said cover inlet, through said plurality of channels in parallel, to said cover outlet.

4. The assembly of claim 1, wherein said fluid circulation structure comprises:
a plurality of high thermal conductivity fins in thermal and mechanical contact with said base, said fins forming a plurality of fluid flow channels;
an input conduit in said cover, said input conduit in fluid flow communication with said cover inlet, said input conduit in fluid flow communication with one opening of at least one of said plurality of channels;
an output conduit in said cover, said output conduit in fluid flow communication with said cover outlet, said output conduit in fluid flow communication with an opposing end of at least one other of said plurality of channels;
a plurality of channel end connectors in said cover, each of said channel end connectors forming a fluid flow connection between one end of at least one set of channels, and one end of at least one other channel; and
wherein said input conduit, said channels, said channel end connectors, and said output conduit form a serpentine, serial fluid flow path from said cover inlet to said cover outlet.

5. The assembly of claim 1, wherein said assembly forms a series fluid flow path among said cold plates.

6. The assembly of claim 1, wherein said assembly forms a parallel fluid flow path among said cold plates.

7. The assembly of claim 1, wherein said assembly forms a combination serial and parallel fluid flow path among said cold plates.

8. The assembly of claim 1, further comprising a cooling fluid.

9. A fluid-coolable electronic module assembly comprising:
a plurality of electronic module substrate assemblies, each of said electronic module substrate assemblies having:
a substrate; and
at least one electronic device electrically connected to said substrate;
a plurality of cold plates, each of said cold plates associated with one of said plurality of electronic module substrate assemblies, each of said cold plates having:
a high thermal conductivity cold plate base, said cold plate base also providing a high thermal conductivity module cap;
a nonmetallic cold plate cover having at least one cover fluid inlet and at least one cover fluid outlet, said cover being sealably affixed to said base; and
a fluid circulation structure for directing fluid flow from said at least one cover fluid inlet to said at least one cover fluid outlet;
a plurality of flexible, nonmetallic fluid distribution conduits in fluid flow communication with said cover fluid inlets and cover fluid outlets, said conduits being bonded to said cover fluid inlets and cover fluid outlets; and
wherein said cold plates and conduits form an assembly for distributing a cooling fluid to said plurality of electronic module substrate assemblies, said fluid distribution assembly having at least one assembly fluid inlet and at least one assembly fluid outlet, said assembly having connectors only at said at least one assembly fluid inlet and said at least one assembly fluid outlet.

10. The assembly of claim 9, further comprising a cooling fluid.

11. The assembly of claim 9, said assembly having one assembly fluid inlet and one assembly fluid outlet.

12. The assembly of claim 9, wherein at least one of said plurality of modules is not coplanar with others of said plurality of modules.

13. The assembly of claim 9, wherein said fluid circulation structure comprises:
a plurality of high thermal conductivity fins in thermal and mechanical contact with said base, said fins forming a plurality of fluid flow channels;
an input plenum in said cover, said input plenum in fluid flow communication with said cover inlet, said input plenum in fluid flow communication with one opening of each of said plurality of channels;
an outlet plenum in said cover, said output plenum in fluid flow communication with an opposing opening of each of said plurality of channels, said output plenum in fluid flow communication with said cover outlet; and
wherein said input plenum, said channels, and said output plenum direct fluid flow from said cover inlet, through said plurality of channels in parallel, to said cover outlet.

14. The assembly of claim 9, wherein said fluid circulation structure comprises:
a plurality of high thermal conductivity fins in thermal and mechanical contact with said base, said fins forming a plurality of fluid flow channels;
an input conduit in said cover, said input conduit in fluid flow communication with said cover inlet, said input conduit in fluid flow communication with one opening of at least one of said plurality of channels;
an output conduit in said cover, said output conduit in fluid flow communication with said cover outlet, said output conduit in fluid flow communication with an opposing end of at least one other of said plurality of channels;
a plurality of channel end connectors in said cover, each of said channel end connectors forming a fluid flow connection between one end of at least one set of channels, and one end of at least one other channel; and
wherein said input conduit, said channels, said channel end connectors, and said output conduit form a serpentine, serial fluid flow path from said cover inlet to said cover outlet.

15. The assembly of claim 9, wherein said assembly forms a series fluid flow path among said covers.

16. The assembly of claim 9, wherein said assembly forms a parallel fluid flow path among said covers.

17. The assembly of claim 9, wherein said assembly forms a combination serial and parallel fluid flow path along said covers.
